(19) United States
(12) Patent Application Publication
(10) Pub. No.: US 2022/0155022 A1
(43) Pub. Date: May 19, 2022

(54) HEAT DISSIPATION DEVICE

(71) Applicants: Inventec (Pudong) Technology Corporation, Shanghai (CN); INVENTEC CORPORATION, Taipei City (TW)

(72) Inventors: Kai-Yang Tung, Taipei City (TW); Hung-Ju Chen, Taipei City (TW)

(21) Appl. No.: 17/338,698

(22) Filed: Jun. 4, 2021

(30) Foreign Application Priority Data
Nov. 19, 2020 (CN) 202011298468.5

(51) Int. Cl. F28D 15/02

(52) U.S. Cl. CPC F28D 15/025

(57) ABSTRACT

A heat dissipation device includes a first pipeline and a second pipeline. The first pipeline is configured to circulate a first fluid. The second pipeline is configured to circulate a second fluid. The second pipeline has a sleeve section, an input portion, and an output portion. The sleeve section sleeved with a part of the first pipeline to form a circulation tunnel between the sleeve section and the part of the first pipeline. The input portion and the output portion are connected to two ends of the sleeve section respectively.

### CROSS-REFERENCE TO RELATED APPLICATION

This application claims priority to China Application Serial Number 202011298468.5 filed Nov. 19, 2020, which is herein incorporated by reference in its entirety.

### BACKGROUND

### Field of Disclosure

The present disclosure relates to a heat dissipation device.

### Description of Related Art

The principle of a common thermosiphon heat dissipation device is using the phase change between gas state and liquid state of the refrigerant to help dissipating heat of the heat source. The liquid state refrigerant absorbs heat and turns into gas state. The gaseous refrigerant is then cooled at the condensation end to condense into the liquid state and returns to the heat source. The heat dissipation efficiency of this kind of heat dissipation device will dependent on the cooling efficiency of the condensation end.

Currently, the condensation end uses low temperature liquid to cool the gaseous refrigerant. The gaseous liquid and the low-temperature liquid circulate in two independent pipelines respectively. Usually the two independent pipelines will contact with each other through thermal interface material, so that the two liquids reach thermal equilibrium through heat conduction. However, the thermal exchange efficiency between the gaseous refrigerant and the low-temperature liquid is hindered by barriers of various materials, which reduces the heat dissipation efficiency of the heat dissipation device.

Therefore, how to provide a heat dissipation device to solve the above problems becomes an important issue to be solved by those in the industry.

### SUMMARY

According to this, the present disclosure provides a heat dissipation device to solve the above problems.

The disclosure provides a heat dissipation device which includes a first pipeline and a second pipeline. The first pipeline is configured to circulate a first fluid. The second pipeline is configured to circulate a second fluid and includes a sleeve section, an input portion, and an output portion. The sleeve section is sleeved with a part of the first pipeline to form a circulation tunnel between the sleeve section and the part. The input portion is connected to the sleeve section. The output portion is connected to the sleeve section.

In other embodiment, the sleeve section sleeved outside the part of the first pipeline, and the circulation tunnel is configured to circulate the second fluid.

In other embodiment, the sleeve section includes a cover portion, a first sealing part and a second sealing part. The cover portion covers the part of the first pipeline and has a first end and a second end. The first sealing part is connected to the first end and the first pipeline air tightly. The second sealing part is connected to the second end and the first pipeline air tightly.

In other embodiment, the sleeve section has opposite two ends. Connections of the input portion, the output portion and the sleeve section are between the two ends.

In other embodiment, the sleeve section is sleeved inside the part of the first pipeline, and the circulation tunnel is configured to circulate the first fluid.

In other embodiment, the sleeve section has opposite two ends. The input portion and the output portion are connected to the two ends of the sleeve section respectively.

In other embodiment, the first pipeline has two holes. The input portion and the output portion pass through the two holes respectively.

In other embodiment, the first pipeline is connected to the input portion and the output portion air tightly.

In other embodiment, the heat dissipation device further includes an evaporator connected to the two ends of the first pipeline.

In other embodiment, the first fluid is refrigerant, and the second fluid is water.

According to the above description, in the present disclosure, the second pipeline includes a sleeve section that is sleeved with a part of the first pipeline. At the sleeved portion, there is only one pipe wall separates the first fluid and the second fluid. Compared with prior arts using a double-layer metal wall and a thermal interface material to achieve the isolation, the foregoing features of the present disclosure can improve the thermal exchange efficiency. Moreover, compared with the prior arts, the heat dissipation device that formed with sleeved portion in the present disclosure uses less space, so the space configuration of the heat dissipation device can be more flexible.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a perspective view of a heat dissipation device according to one embodiment of the present disclosure;

FIG. 2A is a partial cross-sectional view of the heat dissipation device shown in FIG. 1;

FIG. 2B is a partial perspective view of the heat dissipation device shown in FIG. 1;

FIG. 3 is a partial cross-sectional view of a heat dissipation device according to another embodiment of the present disclosure; and

FIG. 4 is a schematic diagram of application of a heat dissipation device according to one embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

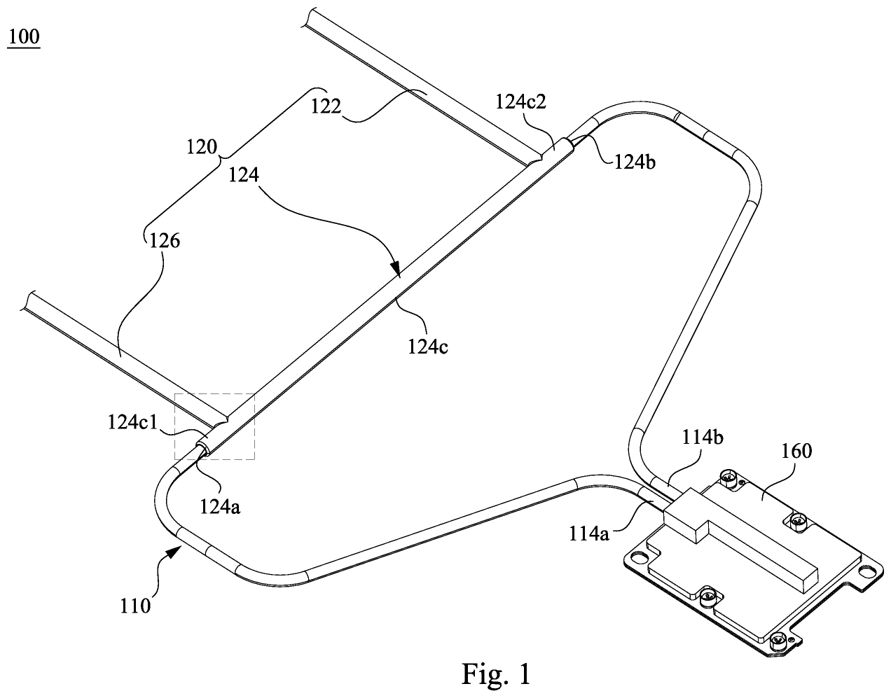

Reference is made to FIG. 1. FIG. 1 is a perspective view of a heat dissipation device 100 according to one embodiment of the present disclosure. As shown in FIG. 1, a heat dissipation device 100 includes a first pipeline 110 and a second pipeline 120. In some embodiments, the material for manufacturing the first pipeline 110 and the second pipeline 120 contains copper or aluminum, but the present disclosure is not limited thereto. In some embodiments, the cross sections of the first pipeline 110 and the second pipeline 120 are in circle or square, but the present disclosure is not limited thereto.

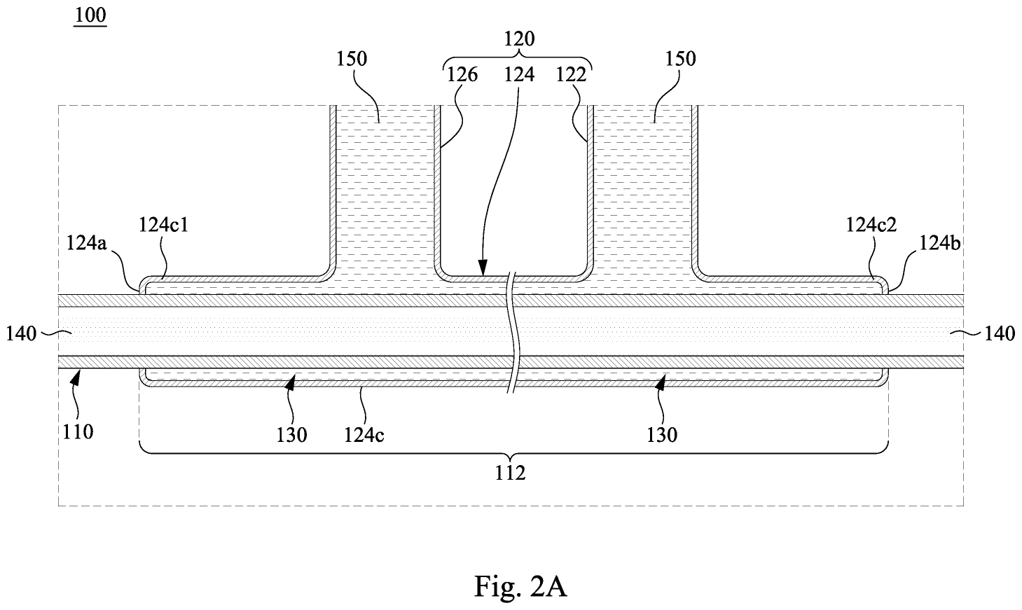

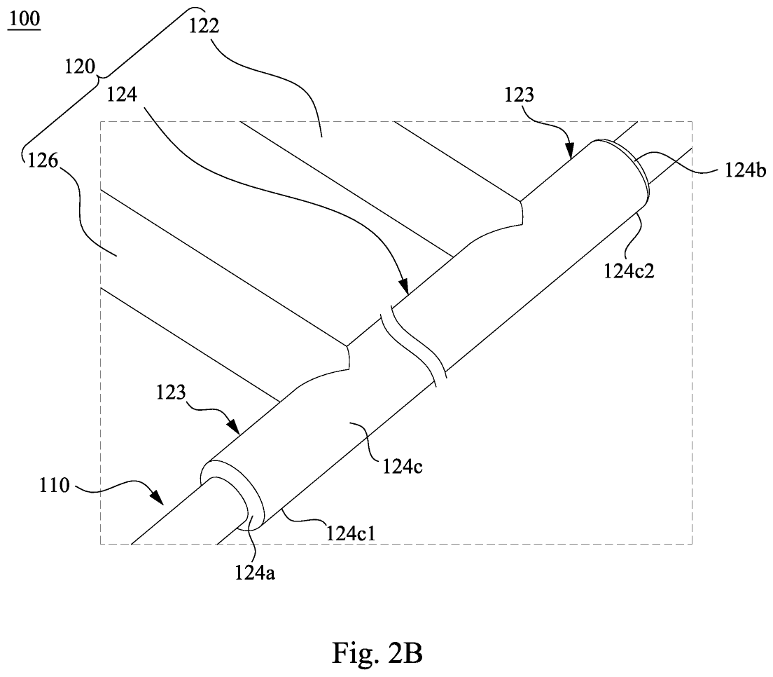

Reference is made to FIG. 2A. FIG. 2A is a partial cross-sectional view of the heat dissipation device 100 shown in FIG. 1. As shown in FIG. 2A, the first pipeline 110 circulates a first fluid 140 therein. The second pipeline 120 circulates a second fluid 150 therein. For example, in some embodiments, the first fluid 140 is refrigerant, and the second fluid 150 is cooling water, but the present disclosure is not limited thereto. As shown in FIG. 1 and FIG. 2A, the second pipeline 120 includes a sleeve section 124, an input portion 126, and an output portion 122. The sleeve section 124 of the second pipeline 120 is sleeved with a part 112 of the first pipeline 110. A circulation tunnel 130 is formed between the sleeve section 124 and the part 112 of the first pipeline 110. The input portion 126 and the input portion 126 of the second pipeline 120 are connected to the sleeve section 124 respectively.

In a specific embodiment of the present disclosure, as shown in FIG. 1 and FIG. 2A, the sleeve section 124 of the second pipeline 120 is sleeved outside the part 112 of the first pipeline 110. The first fluid 140 circulates inside the first pipeline 110, and the second fluid 150 circulates inside the circulation tunnel 130. Take the above embodiment for example, the first fluid 140 is refrigerant and the second fluid 150 is cooling water. The refrigerant and the cooling water can reach thermal equilibrium through the thermal conduction of the part 112 of the first pipeline 110, and thus cool down the refrigerant. The cooling principle is that when the first fluid 140 circulating in the first pipeline 110 passes through the sleeve section 124 of the second pipeline 120, the second fluid 150 and the first fluid 140 will achieve thermal equilibrium through the thermal conduction of the pipe wall of the part 112 of the first pipeline 110. For example, in specific embodiments, the first fluid 140 is refrigerant, and the refrigerant will phase change into gaseous state at high temperature. When the gaseous refrigerant passes through the sleeve section 124, its temperature will reduce due to the thermal exchange with the second fluid 150 (in specific embodiments, the second fluid 150 is cooling water). The cooled gaseous refrigerant will condense on the inner wall of the first pipeline 110 and change phase to liquid refrigerant.

As shown in FIG. 1, in some specific embodiments, the heat dissipation device 100 also includes an evaporator 160. The evaporator 160 is connected to the two sides 114a, 114b of the first pipeline 110. In some embodiments, the evaporator 160 is disposed on the heat source (not shown) to absorb the heat and conduct it to the first fluid 140 inside the first pipeline (see FIG. 2A).

Reference is made to FIG. 2B. FIG. 2B is a partial perspective view of the heat dissipation device 100 shown in FIG. 1. As shown in FIG. 2B, the sleeve section 124 of the second pipeline 120 includes a cover portion 124c, a first sealing part 124a and a second sealing part 124b. The cover portion 124c covers the part 112 of the first pipeline 110, and has a first end 124c1 and a second end 124c2. The first sealing part 124a is connected to the first end 124c1 and the first pipeline 110 air tightly. The second sealing part 124b is connected to the second end 124c2 and the first pipeline 110 air tightly. In other words, the structures formed by the first sealing part 124a and the second sealing part 124b, respectively with the first pipeline 110 can be regarded as two blind tube structures 123 that respectively extend from the first end 124c1 and the second end 124c2 of the cover portion 124c. More specifically, one of the blind tube structures 123 is formed by the first sealing part 124a and a part of the cover portion 124c between the first end 124c1 and the input portion 126. The second sealing part 124b and a part of the cover portion 124c between the second end 124c2 and the output portion 122 form another blind tube structure 123. Connections of the input portion 126 and the output portion 122 of the second pipeline 120 respectively connected to the sleeve section 124 are located between the first end 124c1 and the second end 124c2 of the cover portion 124c.

As the illustrated embodiment shown in FIG. 2B, the above blind tube structures 123 are the parts of the cover portion 124c of the second pipeline 120 extend along the extending direction of the part 112 of the first pipeline 110. At two distal ends of the blind tube structures 123, the circulation tunnel 130 (see FIG. 2A) between the first pipeline 110 and the second pipeline 120 is sealed to prevent the second fluid 150 from leaking out from the heat dissipation device 100. In other words, in some specific embodiments, any one of the input portion 126 and the output portion 122 form a T-shaped structure with the sleeve section 124. This kind of T-shape structure can reduce the manufacture difficulty of the heat dissipation device 100. For example, in the actual manufacturing steps of the heat dissipation device 100, if the junctions of the first sealing part 124a and the input portion 126 respectively with the cover portion 124c coincide, the irregular junctions will increase the welding difficulty. Therefore, by adopting the above T-shaped structure, two different welding surfaces can be separated during manufacturing and thus reduce the manufacture difficulty of the heat dissipation device 100.

As shown in FIG. 2A, in some specific embodiments on the present disclosure, the first pipeline 110 is hermetically connected to the first end 124c1 and the second end 124c2 of the cover portion 124c respectively through the first sealing part 124a and the second sealing part 124b, so as to prevent the second fluid 150 from leaking out of the heat dissipation device 100. That is, the connecting interfaces between the first pipeline 110 and the cover portion 124c are formed by the first sealing part 124a and the second sealing part 124b respectively. Between the first sealing part 124a and the second sealing part 124b, the input portion 126 and the output portion 122 are connected to the second pipeline 120 and the cover portion 124c respectively.

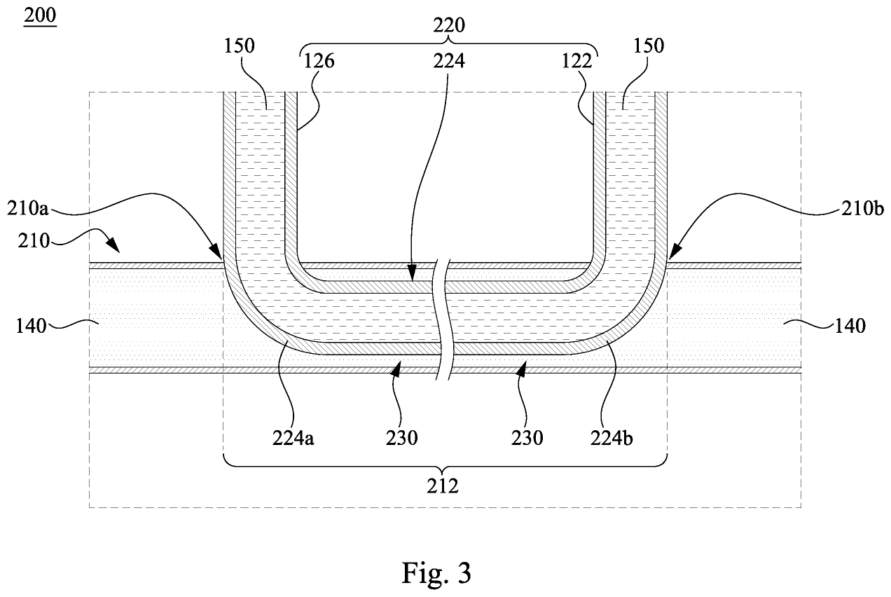

Reference is made to FIG. 3. FIG. 3 is a partial cross-sectional view of a heat dissipation device 200 according to another embodiment of the present disclosure. As shown in FIG. 3, the first pipeline 210 has two holes 210a, 210b and a part 212 that is sleeved with the second pipeline 220. The second pipeline 220 has a sleeve section 224, an input portion 126, and an output portion 122. The input portion 126 and the output portion 122 are similar or the same as the structures shown in the heat dissipation device 100, and thus do not describe herein. The sleeve section 224 of the second pipeline 220 is sleeved inside the part 212 of the first pipeline 210. The circulation tunnel 230 that is located between the first pipeline 210 and the sleeve section 224 circulates the first fluid 140. The sleeve section 224 has opposite two ends 224a, 224b. The input portion 126 and the output portion 122 are connected to the two ends 224a, 224b of the sleeve section 224 respectively. The two ends 224a, 224b of the sleeve section 224 pass out from the two holes 210a, 210b of the first pipeline 210 respectively. The two ends 224a, 224b are air tightly connected to the input portion 126 and the output portion 122 to prevent the first fluid 140 from leaking out from the connected interfaces.

With the above structural configuration, when the first fluid 140 circulating in the first pipeline 210 passes through the sleeve section 224 of the second pipeline 220, the second fluid 150, and the first fluid 140 can achieve thermal equilibrium through the thermal conduction of the pipe wall of the sleeve section 224.

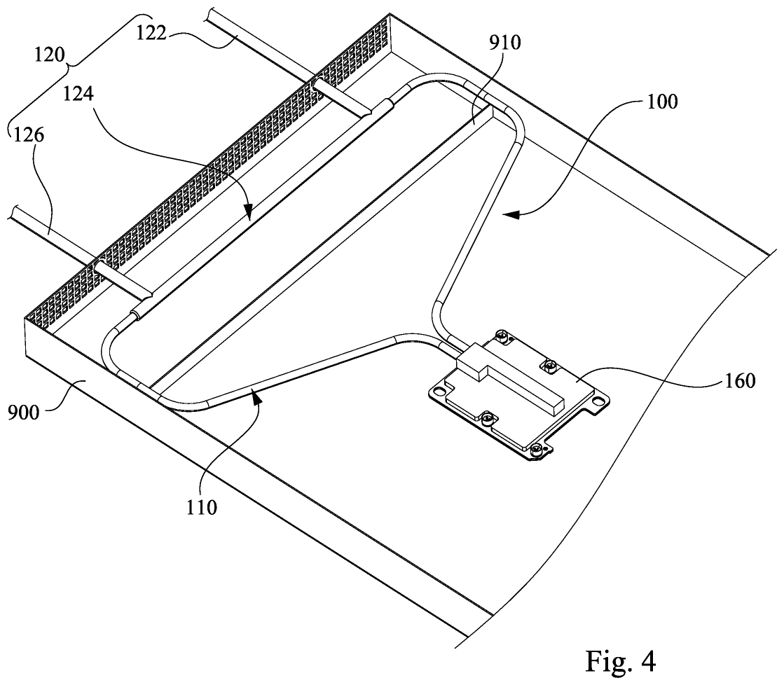

Reference is made to FIG. 4. FIG. 4 is a schematic diagram of application of the heat dissipation device 100 according to one embodiment of the present disclosure. The heat dissipation device 100 is installed in the housing 900 (e.g. a housing of a server). The input portion 126 and the output portion 122 pass through a side of the housing 900 and extend to the outside of the housing 900. The sleeve section 124 of the heat dissipation device 100 and the evaporator 160 are isolated at two different areas by a partition 910 of the housing 900.

In the specific embodiment in FIG. 4, the evaporator 160 is configured to directly contact with the heat source (not shown) in the housing 900 and conduct heat to the first pipeline 110. Reference is made to FIG. 2A and FIG. 4. The first fluid 140 and the second fluid 150 can achieve thermal exchange through the pipe wall of the part 112 of the first pipeline 110 to cool down the first fluid 140.

In other embodiments, the first pipeline 110 and the second pipeline 120 in FIG. 4 can be replaced by the first pipeline 210 and the second pipeline 220 in FIG. 3 respectively, such that the first fluid 140 and the second fluid 150 can achieve thermal exchange through the pipe wall of the sleeve section 224 of the second pipeline 220 to cool down the first fluid 140. Reference is made to FIG. 4. In some embodiments, the outer sides of the sleeve section 124, 224 can be further installed with exhaust devices (not shown, e.g. fans) to help cooling down the heat dissipation device 100.

From the above detail description related the embodiments of the present disclosure, it can be clearly seen that, in the heat dissipation device of the present disclosure, and the second pipeline includes a sleeve section that is sleeved with a part of the first pipeline. At the sleeved portion, only has one pipe wall to separate the first fluid and the second fluid. Compare with the prior arts using double-layer metal wall and thermal interface material to achieve the isolation, the previous characteristics of the present disclosure can improve the thermal exchange efficiency. Also, compare with the prior arts, the heat dissipation device that formed with sleeved portion in the present disclosure uses less space, and thus the dispose of the heat dissipation device can be more flexible.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A heat dissipation device comprising:
a first pipeline configured to circulate a first fluid; and
a second pipeline configured to circulate a second fluid and comprising:
a sleeve section sleeved with a part of the first pipeline to form a circulation tunnel between the sleeve section and the part;
an input portion connected to the sleeve section; and
an output portion connected to the sleeve section.

2. The heat dissipation device of claim 1, wherein the sleeve section is sleeved outside the part of the first pipeline, and the circulation tunnel is configured to circulate the second fluid.

3. The heat dissipation device of claim 2, wherein the sleeve section comprises:
a cover portion covering the part of the first pipeline and having a first end and a second end;
a first sealing portion hermetically connected to the first end and the first pipeline; and
a second sealing portion hermetically connected to the second end and the first pipeline.

4. The heat dissipation device of claim 2, wherein the sleeve section has opposite two ends, and connections of the input portion and the output portion respectively connected to the sleeve section are between the two ends.

5. The heat dissipation device of claim 1, wherein the sleeve section is sleeved inside the part of the first pipeline, and the circulation tunnel is configured to circulate the first fluid.

6. The heat dissipation device of claim 5, wherein the sleeve section has opposite two ends, and the input portion and the output portion are connected to the two ends of the sleeve section respectively.

7. The heat dissipation device of claim 5, wherein the first pipeline has two holes, and the input portion and the output portion pass through the two holes respectively.

8. The heat dissipation device of claim 5, wherein the first pipeline is hermetically connected to the input portion and the output portion.

9. The heat dissipation device of claim 2, further comprising an evaporator connected to two ends of the first pipeline.

10. The heat dissipation device of claim 2, wherein the first fluid is refrigerant and the second fluid is water.
